(19) United States
(12) Patent Application Publication
(10) Pub. No.: US 2015/0079719 A1
(43) Pub. Date: Mar. 19, 2015

(54) SYSTEMS AND METHODS FOR FLIPPING SEMICONDUCTOR BODIES DURING A MANUFACTURING PROCESS

(71) Applicant: JiFu Machinery & Equipment Inc., Mountain View, CA (US)

(72) Inventor: Linh Can, San Jose, CA (US)

(73) Assignee: JiFu Machinery & Equipment Inc., Mountain View, CA (US)

(21) Appl. No.: 14/028,140

(22) Filed: Sep. 16, 2013

(51) Int. Cl. H01L 31/18; B05C 9/12; B65G 47/248

(52) U.S. Cl. CPC H01L 31/18; B65G 47/248; B05C 9/12
USPC 438/61; 414/758; 118/500

(57) ABSTRACT

In one embodiment, a method (e.g., a method for forming one or more semiconductor layers on a device) includes modifying a first side of a first semiconductor body inside of a processing system to at least partially manufacture one or more photovoltaic modules; flipping the first semiconductor body over inside the processing system; and modifying an opposite, second side of the first semiconductor body inside of the processing system to continue fabrication of the one or more photovoltaic cells, wherein modifying at least one of the first side or second side of the first semiconductor body is performed in at least one of a reduced pressure or increased temperature environment of the processing system and flipping the first semiconductor body is performed without removing the first semiconductor body from the processing system.

### BACKGROUND

The manufacturing of semiconductor devices such as photovoltaic modules can involve many processes. These processes may include heating, cooling, etching, material deposition, and doping of materials onto a semiconductor body.

Some systems used to manufacture semiconductor devices such as photovoltaic modules or cells include several chambers connected with each other. Some of these chambers are heated and/or maintain a relatively low-pressure environment inside the chamber during the processing of semiconductor materials. The semiconductor body may be moved between these chambers after the processing in one chamber is complete.

In order to maintain the elevated temperatures and/or low pressures in the chambers, the chambers may be sealed from the surrounding atmosphere. Sealing the chambers can hinder manipulation of the body, such as changing the orientation of the body. As such, certain chambers may require the semiconductor body to be in a specific orientation prior to entering the chamber, while another subsequent chamber may need the semiconductor body to be in a different orientation. Changing the orientation may also include flipping or rotating the semiconductor body. In some systems, an operator may manually intervene to change the orientation of the body. The operator can remove the semiconductor body from a chamber, change the orientation, and then return the body to the chamber. Alternatively, the operator may reach inside the chamber through hermetically sealed gloves to manipulate the body. This manual intervention may involve breaking the low-pressure seal of the chamber (e.g., eliminated such that the pressure inside the chamber is the same as or closer to atmospheric pressure). Additionally, the temperature inside the chamber may need to be reduced so that the operator can safely manipulate the semiconductor body. After manipulating the semiconductor body, the chamber may need to again reduce the pressure inside the chamber and/or increase the temperature to continue processing the semiconductor body. This changing of the pressures and/or temperatures inside the chambers can consume considerable time and energy, thus reducing efficiency and/or throughput of the manufacturing process. Additionally, because the semiconductor body may be fragile, manual manipulation of the semiconductor body increases the risk of damage to the semiconductor materials.

### BRIEF SUMMARY

In an embodiment, a method (e.g., a method for forming one or more semiconductor layers on a device) includes modifying a first side of a first semiconductor body inside of a processing system to at least partially manufacture one or more photovoltaic modules. The method may include flipping the first semiconductor body over inside the processing system and modifying an opposite, second side of the first semiconductor body inside of the processing system to continue fabrication of the one or more photovoltaic modules. The modification of at least one of the first side or second side of the first semiconductor body is performed in at least one of a reduced pressure or an increased temperature environment of the processing system and flipping the first semiconductor body is performed without removing the first semiconductor body from the processing system.

In an embodiment, a processing system includes one or more upstream chambers configured to modify a first side of a first semiconductor body inside the processing system to at least partially manufacture one or more photovoltaic modules. The processing system may include a flipping assembly configured to be disposed inside a flipping chamber that is downstream from the one or more upstream chambers and configured to receive the first semiconductor body from the one or more upstream chambers. The flipping assembly is configured to flip the first semiconductor body over inside the processing system, and one or more downstream chambers are configured to receive the first semiconductor body after being flipped by the flipping assembly and to modify a second side of a first semiconductor body inside the processing system to at least partially manufacture one or more photovoltaic modules. At least one of the one or more upstream chambers or the one or more downstream chambers are configured to modify the respective first or second side of the semiconductor body in at least one of a reduced pressure or increased temperature environment. The flipping assembly is configured to flip the first semiconductor body over without removing the first semiconductor body from the flipping chamber.

In an embodiment, a flipping system includes a lifting plate configured to move relative to a carrier that holds a semiconductor body above an opening through the carrier. The flipping system may also include a post connected with the lifting plate and configured to move through the opening in the carrier. The post may be configured to separate the semiconductor body from the carrier when the lifting plate moves toward the carrier. A flipping assembly of the flipping system is configured to receive the semiconductor body when the post separates the semiconductor body from the carrier. The flipping assembly includes one or more inflatable bodies configured to be inflated with a fluid in order to expand and engage the semiconductor body. A rotatable shaft is configured to be coupled with the flipping assembly and to rotate in order to rotate the flipping assembly. The flipping assembly may be rotated by the shaft while the one or more inflatable bodies hold the semiconductor body so that the semiconductor body is flipped over.

### BRIEF DESCRIPTION OF THE DRAWINGS

The drawings, in which like numerals represent similar parts, illustrate generally, by way of example, but not by way of limitation, various embodiments discussed in the present document:

FIG. 1 is a cross-sectional view of an example of a photovoltaic module;

FIG. 2 is a perspective view of one example of a multi-chamber system from an operator side of the system;

FIG. 3 is a perspective view of a flipping chamber showing internal components;

FIG. 4 is a perspective view of a flipping assembly;

FIG. 5 is a perspective view of the flipping assembly shown in FIG. 4;

FIG. 5 is a side view of a lifting plate, a post, a plug and a carrier among other components referenced in FIG. 4;

FIG. 6, with continued reference to FIG. 4 is a side view of the post, the lifting plate, the carrier and the body, other components within the flipping chamber;

FIG. 7 is a side view of the grasping cell shown in FIG. 4;

FIG. 8 depicts a flowchart to process a semiconductor body in accordance with one or more embodiments of the systems described herein;

FIG. 9 illustrates a body in a carrier positioned under a grasping cell in a flipping chamber;

FIG. 10 depicts the lifting plate contacting the post;

FIG. 11 illustrates the post and plate in the raised position with the grasping bodies engaging the body;

FIG. 12 is a diagram illustrating the lift plate retreating from the grasping cell with the grasping bodies holding the body;

FIG. 13 is a diagram illustrating the grasping bodies engaging the body while being rotated;

FIG. 14 is a diagram illustrating the body after being rotated;

FIG. 15 is a diagram showing the lifting plate contacting and raising the post to retrieve the body form the grasping cell;

FIG. 16 is a diagram illustrating the grasping bodies releasing the body onto the plug; and

FIG. 17 is a diagram illustrating the post, the plug, and the body in the lowered position.

### DETAILED DESCRIPTION

The foregoing summary, as well as the following detailed description of certain embodiments of the subject matter set forth herein, will be better understood when read in conjunction with the appended drawings. As used herein, an element or step recited in the singular and proceeded with the word “a” or “an” should be understood as not excluding plural of said elements or steps, unless such exclusion is explicitly stated. Furthermore, references to “one embodiment” or “an embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

In the following detailed description, reference is made to the accompanying drawings which form a part hereof, and in which are shown by way of illustration specific embodiments in which the subject matter disclosed herein may be practiced. These embodiments, which are also referred to herein as “examples,” are described in sufficient detail to enable one of ordinary skill in the art to practice the subject matter disclosed herein. It is to be understood that the embodiments may be combined or that other embodiments may be utilized, and that structural, logical, and electrical variations may be made without departing from the scope of the subject matter disclosed herein. The following detailed description is, therefore, not to be taken in a limiting sense, and the scope of the subject matter disclosed herein is defined by the appended claims and their equivalents. In the description that follows, like numerals or reference designators will be used to refer to like parts or elements throughout. In this document, the term “or” is used to refer to a nonexclusive or, unless otherwise indicated.

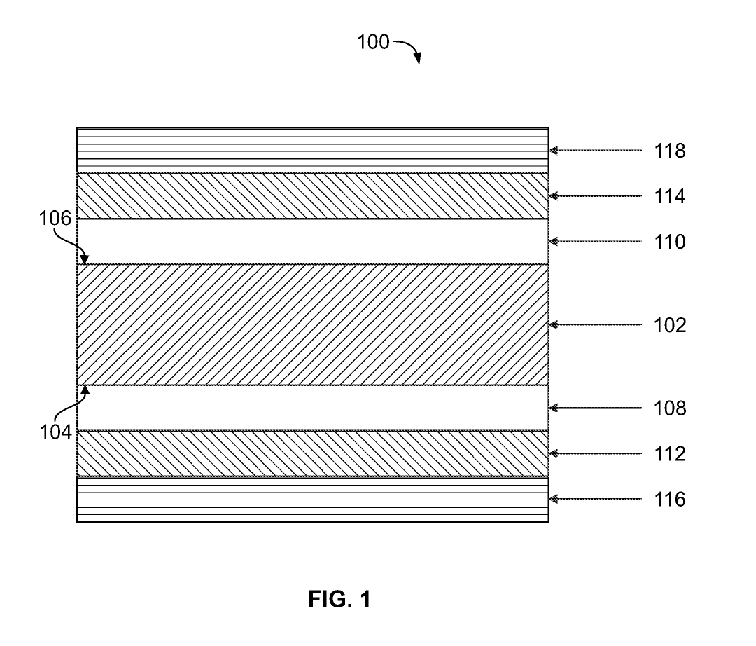

FIG. 1 is a cross-sectional view of an example of a solar or photovoltaic (PV) or module 100. The PV module 100 converts incident light into electrical energy, such as a direct current. The PV module 100 may be a hetrojunction with intrinsic thin layer (HIT) type PV module. The module 100 includes a semiconductor body 102, such as an n-type silicon wafer (crystalline, polycrystalline, microcrystalline, amorphous, or the like) or other semiconductor material. Optionally, the semiconductor body 102 may be a p-type semiconductor wafer or body. The semiconductor body 102 extends between opposite sides 104, 106. First semiconductor layers 108, 110 are disposed on opposite sides of the semiconductor body 102. For example, the first semiconductor layer 108 can directly engage or abut the side 104 and the second semiconductor layer 110 can directly engage or abut the side 106. Optionally, one or more of the first semiconductor layers 108, 110 may be separated from the sides 104, 106 of the semiconductor body 102 by one or more intervening films or layers. In one aspect, the first semiconductor layers 108, 110 are intrinsic silicon layers, such as amorphous silicon layers that are not intentionally doped with any p- or n-type dopants. Alternatively, the first semiconductor layers 108, 110 may include another semiconductor material or may be doped with p- or n-type dopants.

Second semiconductor layers 112, 114 are disposed on opposite sides of the semiconductor body 102 and the first semiconductor layers 108, 110. For example, the second semiconductor layer 112 can directly engage or abut the first semiconductor layer 108 such that the first semiconductor layer 108 is disposed between the semiconductor body 108 and the second semiconductor layer 112. The second semiconductor layer 114 can directly engage or abut the first semiconductor layer 110 such that the first semiconductor layer 110 is disposed between the semiconductor body 108 and the second semiconductor layer 114. Optionally, one or more of the second semiconductor layers 112, 114 may be separated from the respective first semiconductor layers 108, 110 by one or more intervening films or layers. In one aspect, the second semiconductor layers 112, 114 are p-doped silicon layers, such as amorphous silicon layers that are doped with one or more p-type dopants. Alternatively, the second semiconductor layers 112, 114 may include another semiconductor material or may be intrinsic or n-type layers.

Conductive layers 116, 118 are disposed on opposite sides of the semiconductor body 102 and the first and second semiconductor layers 108, 110, 112, 114. For example, the conductive layers 116, 118 may be disposed outside of the body 102 and layers 108, 110, 112, 114. The conductive layer 116 may directly engage or abut the second semiconductor layer 112 and the conductive layer 118 may directly engage or abut the second semiconductor layer 114. Optionally, one or more of the conductive layers 116, 118 may be separated from the respective second semiconductor layers 112, 114 by one or more intervening films or layers. In one aspect, the conductive layers 116, 118 are light-transmissive conductive layers, such as transparent conductive oxide layers (e.g., Indium Tin Oxide, or ITO). Alternatively, the conductive layers 116, 118 may include another conductive material.

In operation, the module 100 receives light through one or more of the conductive layers 116, 118. One or more wavelengths of this light may be absorbed by the first semiconductor layers 108, 110 (and/or one or more of the second semiconductor layers 112, 114 and/or the semiconductor body 108) and converted into electric current. The electric current may be conducted or otherwise conveyed to the conductive layers 116, 118. The conductive layers 116, 118 may be conductively coupled with one or more buses or wires to conduct this electric current out of the module 100.

Manufacturing the module 100 may involve several processes that deposit or dope the layers 108, 110, 112, 114 of the module 100. In one example, prior to depositing the layers 108, 110, 112, 114, the semiconductor body 102 may be placed onto a supporting body, such as a carrier described below, with the side 106 of the body 102 facing away from the carrier and the opposite side 104 facing or engaging the carrier. In such a position, the side 106 is referred to as an exposed side of the body 102 (as this side is exposed) and the side 104 is referred to as a facing side of the body 102 (as this side faces the carrier).

The first semiconductor layer 110 may be deposited onto the exposed side 106, such as by using plasma enhanced chemical vapor deposition (PECVD) or another deposition technique. The second semiconductor layer 114 may then be deposited onto the first semiconductor layer 110, such as by using PECVD or another technique. In order to deposit the first semiconductor layer 108, however, the facing side 104 of the semiconductor body 102 may need to be exposed. At least one embodiment of the subject matter described herein provides an assembly that changes the orientation of the semiconductor body 102 so that the facing side 104 is no longer facing the carrier and the exposed side 106 is no longer exposed. For example, the semiconductor body 102 (with the first and second semiconductor layers 110, 114 disposed thereon) can be flipped so that the exposed side 106 faces (but may not directly engage) the carrier while the facing side 104 is exposed (or faces away from the carrier). In doing so, the side 106 of the semiconductor body 102 changes from being the exposed side to the facing side, and the side 104 of the semiconductor body 102 changes from being the facing side to being the exposed side. The first and second semiconductor layers 108, 112 may then be deposited onto the side 104, similar to as described above in connection with the first and second semiconductor layers 110, 114. The conductive layers 116, 118 may be deposited after formation of the semiconductor layers 108, 110, 112, 114 is complete.

One or more of the above processes may be carried out in non-atmospheric conditions. For example, depositing the semiconductor layers 108, 110, 112, 114 may be performed at an elevated temperature (e.g., at least 200° Celsius) relative to room temperature and/or in a reduced pressure environment (e.g., 3 Torr or less) relative to atmospheric pressure.

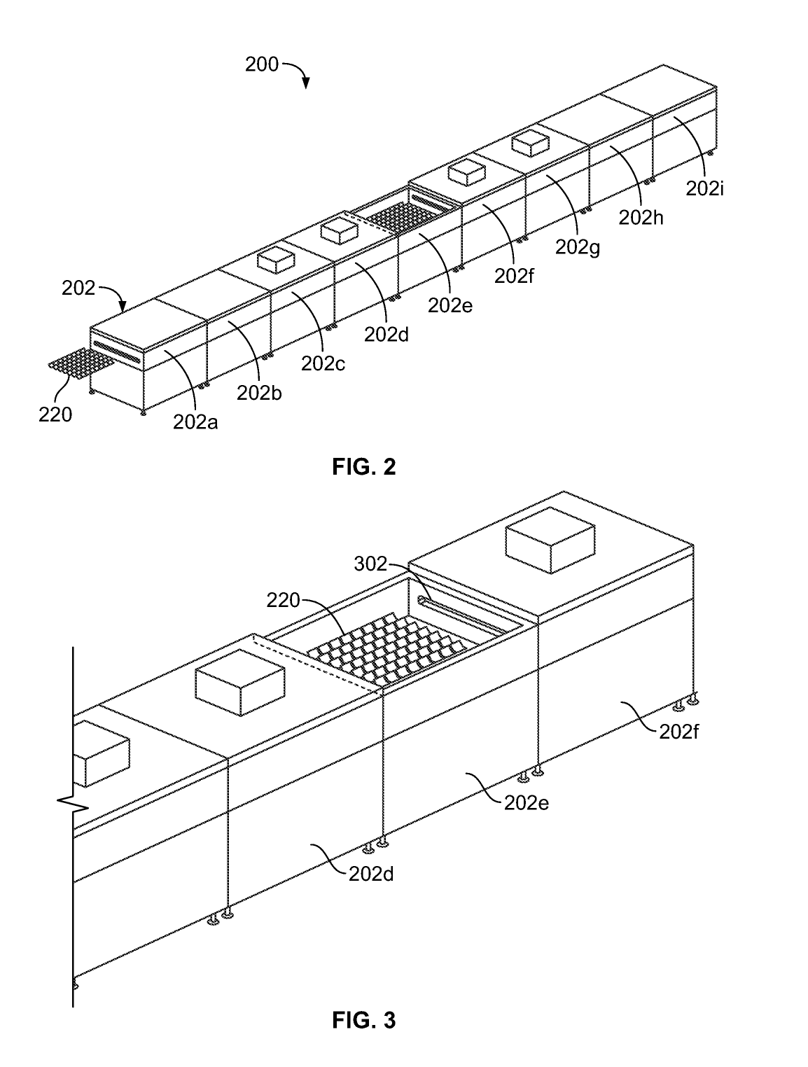

FIG. 2 is a perspective view of one example of a multi-chamber system 200 from an operator side of the system 200. The system 200 processes semiconductor modules, such as the module 100, as one part of a manufacturing process. The system 200 includes several chambers 202 (e.g., chambers 202a-i, although another number of chambers may be present) connected with each other. The chambers 202 may be aligned with each other such that the body 102 can move between the chambers 202 (e.g., such as by a conveyor belt or other conveyance system) while each chamber performs processing on the body 102. The chambers 202 may be sealed with each other such the body 102 is not exposed to the surrounding atmosphere and the chambers 202 may maintain a reduced pressure atmosphere and/or elevated temperature within the volume defined by the interconnected chambers.

The system 200 may include a carrier 220 that supports one or more semiconductor bodies 102 during movement through the processing system 200 so that several modules 100 can be manufactured using the bodies 102, as described above. The carrier 220 may transport one or more bodies 102 concurrently so that the one or more bodies 102 are processed in a chamber 202 at the same time. Additionally, the carrier 220 may include one or more components that mechanically support the body 102 but are not included as part of the module 100 when manufacturing is completed. The carrier 220 may include mechanical provisions to attach the bodies 102 to a conveyor subsystem (not shown).

The conveyor subsystem may move the bodies 102 from chamber 202 to chamber 202. By way of example, the conveyor subsystem may include one or more conveyor belts, chains, belts, or the like, that move the carrier 220 to and through the chambers 202, such as one or more chains or belts that pull or push the carrier 220 (e.g., by attaching to the carrier 220 and moving the chain or belt to move the carrier 220), and the like. The chambers 202 may be arranged such that the conveyor subsystem sequentially moves the carrier 220 between the chambers 202 for the various processing steps or operations.

Returning to the discussion of the multi-chamber processing system 200 of FIG. 2, each chamber 202 may be configured to perform one or more designated functions used to partially manufacture the module 100. For example, in an embodiment, the body 102 may begin the manufacturing process by being loaded into the loading chamber 202a. The loading chamber 202a may be used to place the body 102 onto a carrier 220. Optionally, the loading chamber 202a may be used to engage the body 102 onto a conveyor system. As yet another option, the loading chamber 202a may engage the body 102 or the carrier 220 onto the conveyor system.

The body 102 may then move from the loading chamber 202a to the pre-heating chamber 202b. The pre-heating chamber may increase the temperature of the body 102 to a predetermined level (e.g., at least 200° Celsius). Once the heating chamber 202b heats the body 102, the body 102 may proceed to the processing chambers 202c, 202d, 202f, and 202g.

The body 102 may then proceed to the i-process chamber 202c. The i-process chamber 202c may be configured to use PECVD or another technique to deposit semiconductor layers onto the body 102. The body 102 may enter the i-process chamber 202c such that the exposed side 106 of the body 102 is exposed and the facing side 104 faces the carrier 220 or the conveyor subsystem. Once the body 102 has transitioned to the i-process chamber 202c, the i-process chamber 202c may deposit the first intrinsic semiconductor layer 110 onto the exposed side 106 of the body 102. After processing in the i-process chamber is complete, the body 102 may proceed to the n-process chamber 202d.

The n-process chamber 202d may be configured to deposit the second semiconductor layer 114 on the first semiconductor layer 110 of the body 102. As with the i-process chamber 202c, the n-process chamber may be configured to use PECVD or another technique to deposit the semiconductor layer. After the n-process chamber deposits the second semiconductor layer 114, the body 102 may then proceed to the flipping chamber 202e.

To continue processing, the orientation of the body 102 may need to be changed so that the facing site 104 is no longer facing the carrier 220, and the exposed side 106 is no longer exposed. For example, chamber 202f may be configured as an i-process chamber, similar to the i-process chamber 202c. However, the i-process chamber 202f may be configured to deposit the first semiconductor layer 108 on the facing side 104 of the body 102. As such, the i-process chamber 202f may require the body 102 to change orientation (e.g., be flipped) so that the facing side 104 becomes exposed prior to entering the chamber.

To change orientation of the body 102, the chamber 202e may be configured as a flipping chamber as described in at least one embodiment of the subject matter described herein. The flipping chamber 202e may change the orientation so that the facing side 104 becomes exposed and the exposed side 106 faces the carrier 220. The flipping chamber 202e may be selectively located in the processing system 200 so that the flipping chamber 202e changes the orientation of the body 102 before the body 102 enters the chamber requiring the orientation change.

With continued reference to FIG. 2, FIG. 3 is a perspective view showing the internal components of the chamber 202e. The chamber 202e is shown with the upper housing (e.g., lid) removed for clarity. The carrier 220 may transport the body 102 to chamber 202e from either chamber 202d or 202f. To allow the body 102 to move between the chambers, the chambers 202d, 202e, and 202f may include a corridor or opening 302. The opening 302 may be disposed between the chambers 202e and 202f, such that the carrier 220 may pass through from one chamber to another adjacent chamber. The opening 302 may include a seal or gasket around the perimeter to allow the chambers to remain sealed from the ambient environment in order to maintain a low-pressure and/or elevated temperature within each chamber 202, while allowing the carrier and semiconductor bodies to move into and out of the chamber 202e.

Returning to the description of the system 200 shown in FIG. 2, the flipping chamber 202e may vary in different embodiments. In one embodiment, the location of the flipping chamber 202e may be based on efficiency. For example, the flipping chamber 202e may be located near a chamber that requires frequent flipping in order to reduce the amount of time the body 102 spends traveling to and from the chamber requiring flipping. As another example, the location of the flipping chamber 202e may be based on the strength of the body 102 such that the flipping chamber 202e may be utilized after a sufficient number of layers have been deposited on the body 102.

The flipping chamber 202e may change the orientation of the body 102 while remaining sealed from the ambient atmosphere. Remaining sealed may allow the flipping chamber 202e to maintain a reduced pressure and/or an elevated temperature within the chamber. The flipping chamber 202e may maintain the seal by flipping the body 102 without removing the housing (e.g., lid) of the chamber. Because the flipping chamber 202e may be sealed from the ambient environment, the flipping chamber 202e may flip the body 102 without an external object entering the chamber 202e. For example, the flipping chamber 202e may flip the body 102 without requiring an automated system (e.g., a robot) remove the housing to enter the chamber to grasp and flip the body 102. Similarly, the flipping chamber 202e may flip the body without operator interaction. For example, the flipping chamber 202e may flip the body 102 without requiring an operator with sealed gloves extending into the chamber reach into the chamber 202e to handle the body 102. As such, manual manipulation may reduce efficiency because the system 200 or a chamber 202 may require cooling before the operator can safely handle the body 102. Thus, time and/or energy may be expended cooling and reheating the system 200 and/or chamber 202.

After the flipping chamber 202e changes the orientation of the body 102 (e.g., flips the body 102 over), the facing side 104 becomes exposed and no longer faces the carrier 220 and the exposed side 106 is no longer exposed. Additionally, any semiconductor material that may have been deposited on the body 102 remains affixed to the body so that the material also moves with the body 102. For example, prior to entering the flipping chamber 220, the body 102 may include semiconductor layers 102 and 104 on the exposed side 106. After the flipping chamber 202e flips the body, the semiconductor layers 102 and 104 may no longer be exposed and may face the carrier 220.

The body 102 may exit the flipping chamber 202e after the body 102 has been flipped and continue to the subsequent chambers 202f-202i. The i-process chamber 202f may deposit the first semiconductor layer 108 on the newly exposed side 104 of the body 102. Once the first semiconductor layer 108 has been deposited, the body 102 may continue to the p-process chamber 202g, which may deposit the second semiconductor layer 112 onto the first semiconductor layer 108. The i-process chamber 202f and p-process chamber 202g may use PECVD or another deposition technique, similar to as described above regarding chambers 202c and 202d. The body may then proceed to the cooling chamber 202h. After the body 102 has cooled in the cooling chamber 202h, the body 102 may proceed to the unloading chamber 202i. The unloading chamber may be configured to remove the body 102 from the carrier 220. Alternatively, the unloading chamber may remove any mechanical support material added to the body 102 in the loading chamber 202a. As such, in various embodiments, the system 200 may include other chambers to further process the body to complete manufacturing of the module 100. For example, the system 200 may include additional chambers (not shown) to anneal and/or etch the body 102. The conductive layers 116, 118 may be deposited onto the semiconductor layers 110, 112 within the system 200 or after removal of the semiconductor body 102 and layers 108, 110, 112, 114

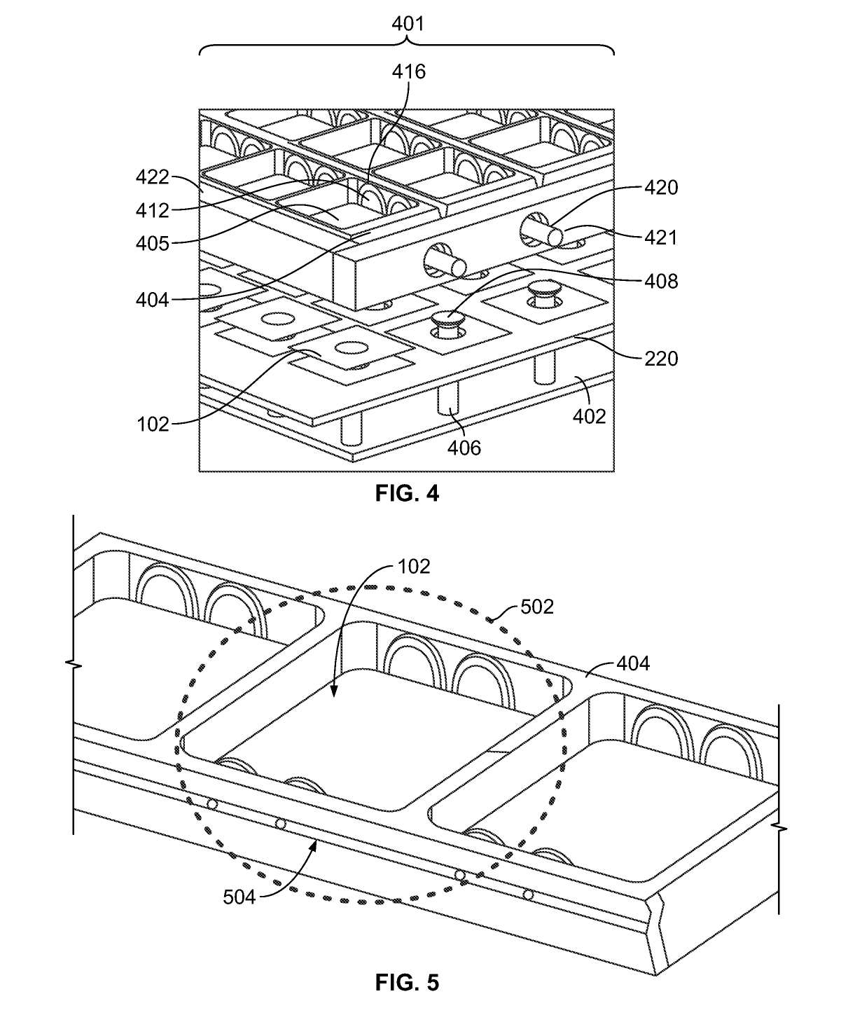

With continued reference to FIG. 2, FIG. 4 is a perspective view of a flipping assembly 401. The flipping chamber 202e may include one or more flipping assemblies 401 that may be used to perform the flipping operation described here. The flipping assembly 401 may include several components. As shown in FIG. 4, the body 102 may be supported on a carrier 220 with several other bodies. The body 102 may be positioned under a chassis 422. The chassis 422 may support one or more grasping cell arrays 404. The number of grasping cell arrays 404 may be based on the number of bodies 102 that the flipping chamber 202e is to flip over. The grasping cell array 404 may be supported within the chassis 422 by one or more rotation shafts 420 located at opposite ends of the grasping cell array 404. The chassis 422 may include an opening 421 to receive the rotation shaft 420. A portion of the rotation shaft 420 may extend through opening 421. Similarly, the chassis 422 may include a plurality of openings 421 to support multiple grasping cell arrays 404. The opening 421 may include provisions (e.g., bushings or bearings) to allow the rotation shaft 420 and the grasping cell array 404 to unrestrictedly rotate while supporting the grasping cell array 404. Additionally, the grasping cell array 404 may rotate within the chassis 422 such that the grasping cell array 404 does not interfere or touch any other grasping cell array 404 or the chassis 422. Optionally, the rotation shaft may rotate the flipping assembly 401 within the flipping chamber 202e.

FIG. 5 is a perspective view of the grasping cell array 404 shown in FIG. 4. The region 502, indicated by the dashed line, shows an individual grasping cell 405 within a grasping cell array 404. The grasping cell 405 is shown holding the body 102. Further, the grasping cell array 404 may include one or more grasping cells 405. As shown in FIG. 5, several grasping cells 405 may be arranged such that each grasping cell 405 shares a side with an adjacent grasping cell. The grasping cell array 404 may also include a delivery channel 504 traversing the one or more sides of the grasping cell array 404. Details of the operation of the grasping cell 405 and delivery channel 504 are discussed below.

The grasping cell array 404 may include a delivery channel 504. The delivery channel 504 may be a device that delivers a fluid to one or more grasping cells 405. For example, the delivery channel 504 may be a series of tubes that join each grasping cell 405 in a grasping cell array 404. Additionally, the delivery channel 504 may interface with one or more grasping cell arrays 404 in the chassis 422. The delivery channel 504 may then interface or connect to a pressure or fluid regulator that may control the fluid level (e.g., pressure) inside the delivery channel 504. The fluid regulator may be part of ancillary support equipment that interfaces with the flipping chamber 202e. For example, the fluid regulator may be part of a pumping chamber which maintains a low pressure environment within the system 200.

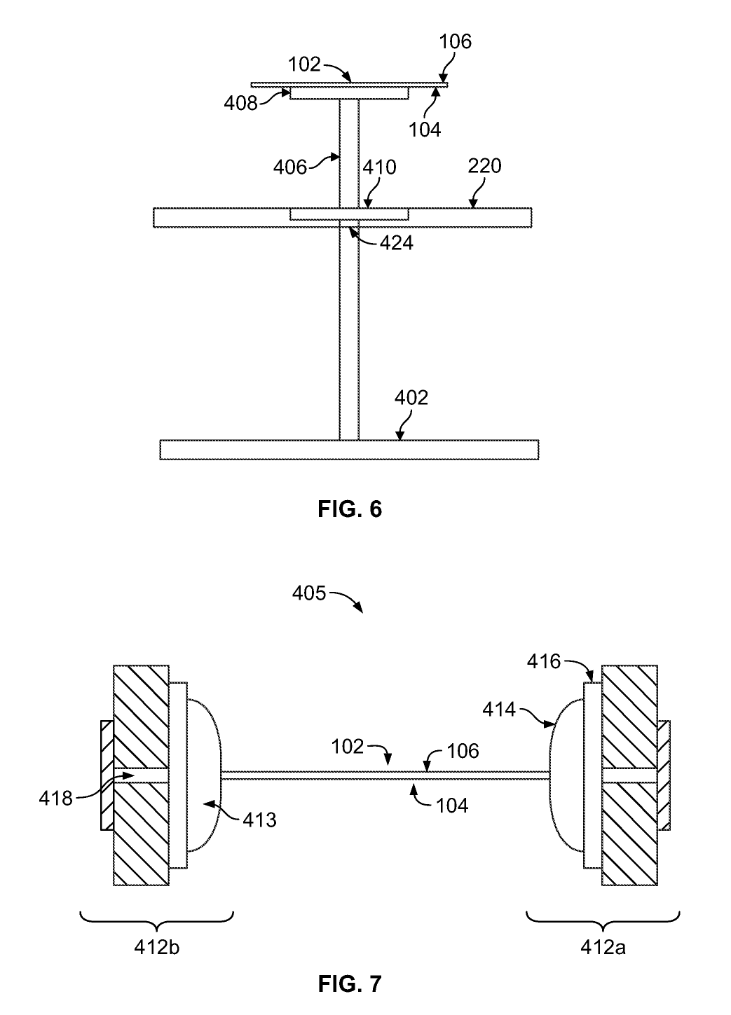

FIG. 6, with continued reference to FIG. 4, is a side view of the post 406, the lifting plate 402, the carrier 220 the body 102, and other components within the flipping chamber 202e. As depicted in FIG. 6, the carrier 220 may include a post 406. The carrier 220 may include an aperture or opening 424 to allow the post 406 to travel through the opening 424. Additionally, the carrier 220 may restrict movement of the post 406 such that the post 406 may move along the length of the post 406 (e.g., up and down) while substantially eliminating lateral motion (e.g., side-to-side motion). As used herein, the post 406 is in the lowered position when a substantial portion of the post 406 is below the carrier 220. Conversely, the post 406 is in the raised position when a majority of the post 406 extends above the carrier 220.

The post 406 may also include a plug 408 situated on one or more ends of the post 406. The plug 408 may limit the length of travel of the post 406. The plug 408 may be a disk-like structure securely fastened to the post 406. As such, the plug 408 may maintain the post 406 within the carrier 220 (e.g., keeps the post from falling out of the carrier 220). The plug 408 may also increase the contact area between the body 102 and the post 406. For example, the plug 408 may be configured (e.g., sized and shaped) to increase the contact area between the plug 408 and the body 102 in order to increase the stability of the body 102 while situated on the post 406. The carrier 220 may include a recess 410 to receive the plug 408 when the post 406 is in the lowered position. The recess 410 may be a portion of the planar surface of the carrier 220 that is set back from the remainder of the surface of the carrier 220. The recess 410 may be of a sufficient length and depth to receive and retain the plug 408 while the post 406 is in the lowered position. For example, the carrier 220 may include a groove or recess 410 with a depth based on the thickness of the plug 408 so that the plug 408 fills the recess 410 when the post 406 is in the lowered position.

The flipping chamber 202e may also include a lifting plate 402. The lifting plate 402 may be configured to move vertically within the flipping chamber 202e. The lifting plate 402 may be configured to contact the post 406. As such, movement of the lifting plate 402 may be used to govern the position of the post 406. Because the body 102 may be situated on the plug 408, which is secured to at least one end of the post 406, the lifting plate 402 may raise and lower the body 102 by contacting and lifting the post 406. As such, raising and lowering the post 406 may allow the body 102 raised and lowered. Additionally, the lifting plate 402 may interact with a plurality of posts 406. The lifting plate 402 may be configured with a substantially planar surface to encourage uniform contact with several posts 406, thus allowing several posts 406 to move in unison.

FIG. 7 is a side view of the grasping cell 405 shown in FIG. 4. The grasping cell 405 may include a grasping body 412, a mounting ring 416, and a fluid delivery channel 504, among other components. The grasping body 412 may include a membrane 414, and an internal volume 413. As illustrated, grasping bodies 412a and 412b are shown retaining and holding the body 102.

The grasping body 412 may be configured to hold the body 102. The grasping body 412 may hold the body 102 by engaging one or more edges of the body 102. As used herein, an edge of the body 102 may refer to a surface that extends from a first side (e.g., top) a second side (e.g., bottom) of the body 102. For example, an edge may be the surface extending from the exposed side 106 to the facing side 104 of the body 102. Similarly, an edge may be the surface extending between several layers of semiconductor material. For example, an edge may be the surface extending from the second semiconductor layer 118, to and through the first semiconductor layer 114, and through the body 102.

Furthermore, the body 102 may have one or more edges. For example, the body 102 may have a circular plan form with one edge extending from the first side to the second side. As such the edge may circumnavigate the perimeter of the body 102. As another example, the body 102 may have a rectangular plan form, in which case the body 102 would have four edges. As another example, the body 102 may have a polygonal plan form and may have multiple edges along the perimeter joining the top and bottom sides.

In various embodiments, the grasping cell 405 may be configured with a plurality of grasping bodies 412 such as the grasping body 412a and 412b. Several grasping bodies 412 may be located throughout the internal perimeter of the grasping cell 405. Select sides along the internal walls of the grasping cell 405 may include one or more grasping bodies 412. For example, the grasping cell 405 may include two grasping bodies 412a and 412b diametrically opposed to each other within the grasping cell 405. As another example, the grasping cell 405 may include several grasping bodies 412 along the wall of on each side of the grasping cell 405. As another example, the grasping cell 405 may be configured with one elongated grasping body 412 that surrounds the internal perimeter of the grasping cell 405. As another option, the grasping body 412 may be a series of contiguous grasping bodies 412 that abut one another and surround the internal perimeter of the grasping cell 405. Alternatively, the grasping cell 405 may include multiple grasping bodies 412 distributed vertically along the sides of the grasping cell 405. For example, the grasping cell 405 may include a grasping body 412 located along a top half of one side of the grasping cell 405, and a second grasping body 412 located along a bottom half of the same side of the grasping cell 405.

In various embodiments, the arrangement of the grasping bodies 412 within the grasping cell 405 may be based on the shape of the body 102. For example to grasp a body 102 having a square plan form, the grasping cell 405 may include two grasping bodies 412 diametrically opposed to each other so that the grasping bodies 412 may engage two opposite sides of the body 102. As another example, the grasping cell 405 may include four grasping bodies 412 along each wall within a rectangular grasping cell 405 to engage four sides of a rectangular body 102. As yet another example, to grasp a circular body 102, the grasping cell 405 may be substantially circular and have one elongated grasping body 412 circumnavigating the internal perimeter of the grasping cell 405.

The grasping body 412 may include a member that extends radially inward from the grasping cell 405 to engage an edge of the body 102. In an embodiment, the grasping body 412 may be a rigid body. For example, the grasping body 412 may be an articulated member extending from the grasping cell 405 to contact and secure an edge of the body 102. As another example, the grasping body 412 may comprise an elastic member (e.g., rubber or plastic) disposed on an end of a member, which extends inward within the grasping cell 405 to engage an edge of the body 102. In an embodiment, the grasping body 412 may be an inflatable body. As an inflatable body, the grasping body 412 may inflate or expand to contact and secure the body 102. A membrane 414 on the grasping body 412 may expand to contact at least one edge of the body 102. Conversely, the grasping body 412 may contract to release the body 102.

In various embodiments, the membrane 414 of the grasping body 412 may comprise an elastic material. The elastic material may be sufficiently resilient to allow the membrane 414 to operate (e.g., expand and contract) within the ambient temperature and pressure conditions inside the flipping chamber 202e. For example, an elastomer (e.g., rubber) may be used. The surface of the membrane 414 may be configured to encourage the membrane 414 to grasp an edge of the body 102. For example, the membrane 414 may have a smooth surface to provide a uniform force distribution along an edge of the body 102 when the membrane is inflated. Alternatively, the surface of the membrane 414 may be textured to encourage the grasping body to grip an edge of the body 102.

A fluid may be supplied to the grasping body 412 to cause the membrane 414 to expand or inflate. Conversely, fluid may be removed from the grasping body 412 to cause the membrane to contract. The fluid level may create a pressure difference between the ambient pressure inside the chamber 202e and the internal volume 413 of the grasping body 412, thus causing the membrane 414 to expand or contract. The internal volume 413 may be the volume between the membrane 414 and the edge of the grasping cell 405. Fluid (e.g., a gas or a liquid) may be introduced into the internal volume 413 to cause the membrane 414 to expand. For example, the pressure inside the internal volume 413 may be increased such that the pressure within the volume 413 is greater than the ambient pressure inside the chamber 202e. As such, the membrane 414 may expand outward toward the center of the grasping cell 405 due to the pressure difference. As another example, air pressure inside the delivery channel 504 and the internal volume 413 may be increased to 760 Torr, while the pressure inside the flipping chamber 210 may be less than 760 Torr (e.g. 0.5 to 4 Torr), thus, causing the membrane 414 to expand. Conversely, the membrane 414 may be caused to contract by removing fluid from the internal volume 413. For example, the pressure inside the internal volume 413 may be equalized with the ambient pressure inside the chamber 202e.

The fluid may be any suitable fluid as is known in the art. The fluid type may be based on operational factors within the chamber 202e (e.g., the operating temperature and/or pressure). The fluid may be a compressible fluid (e.g., a gas) or an incompressible fluid (e.g., a liquid). For example, in reactive environments, an inert gas such as air or gaseous nitrogen may be used. Alternatively, in high-pressure environments, the fluid may be an incompressible fluid such as hydraulic fluid. The internal volume 413 and delivery channel 504 may be sealed from the ambient volume within the flipping chamber 202e in order to maintain a pressure difference.

The grasping body 412 may receive fluid through the delivery channel 504. The delivery channel 504 may be embodied as a common fluid conduit that provides fluid to several grasping bodies 412 in a grasping cell 405 concurrently. The chassis 422 may be configured with a fluid delivery system that provides fluid to several delivery channels 504. For example, the fluid delivery system may include a tube connecting to each grasping cell 405. The fluid delivery system may include a pressure regulation subsystem that may control the pressure inside the grasping body 412, and hence the actuation of the membrane 414 of one or more grasping body 412 in the chassis 422.

In an embodiment, the grasping body 412 may include a mounting ring 416. The mounting ring 416 may removably couple the grasping body 412 to the grasping cell 405. As used herein, removably couple means to securely attach, while providing a means for removal. Removably coupling the grasping member 412 to the grasping cell 405 may allow an individual grasping body 412 to be replaced upon malfunction. For example, the membrane 414 may be removed from the grasping cell 412 and replaced upon tearing. To removably couple the grasping body 412 to the grasping cell 405, the grasping cell 405 may include provisions to receive the mounting ring 416. For example, the mounting ring 416 and grasping cell 405 may include threads allowing the mounting ring 416 to screw into the grasping cell 405. Alternatively, the mounting ring 416 may provide a friction fit between the grasping body 412 and the grasping cell 405.

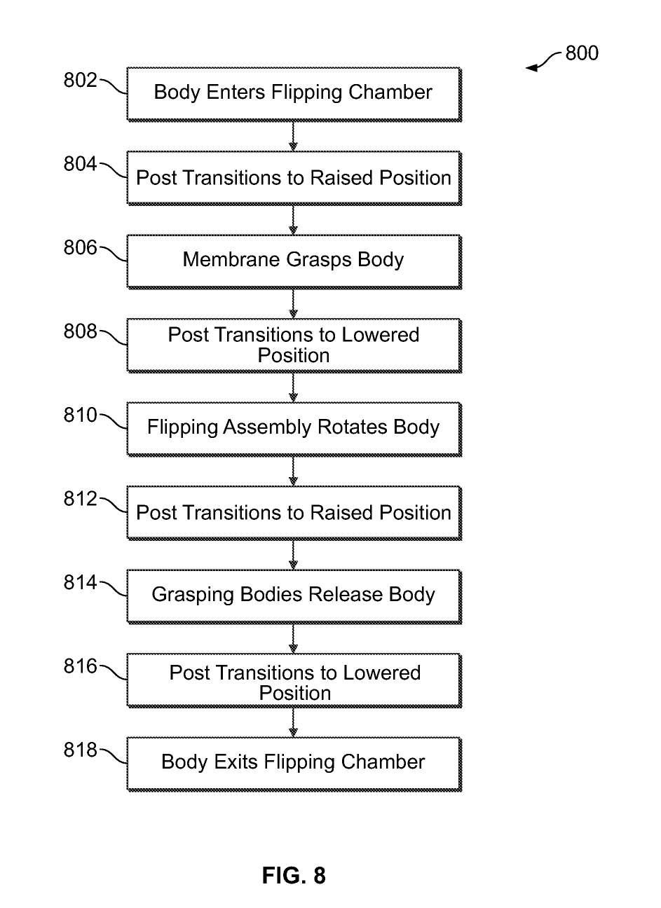

Turning now to FIG. 8, which depicts a flowchart to process a semiconductor body 102 in accordance with one or more embodiments of the systems described herein.

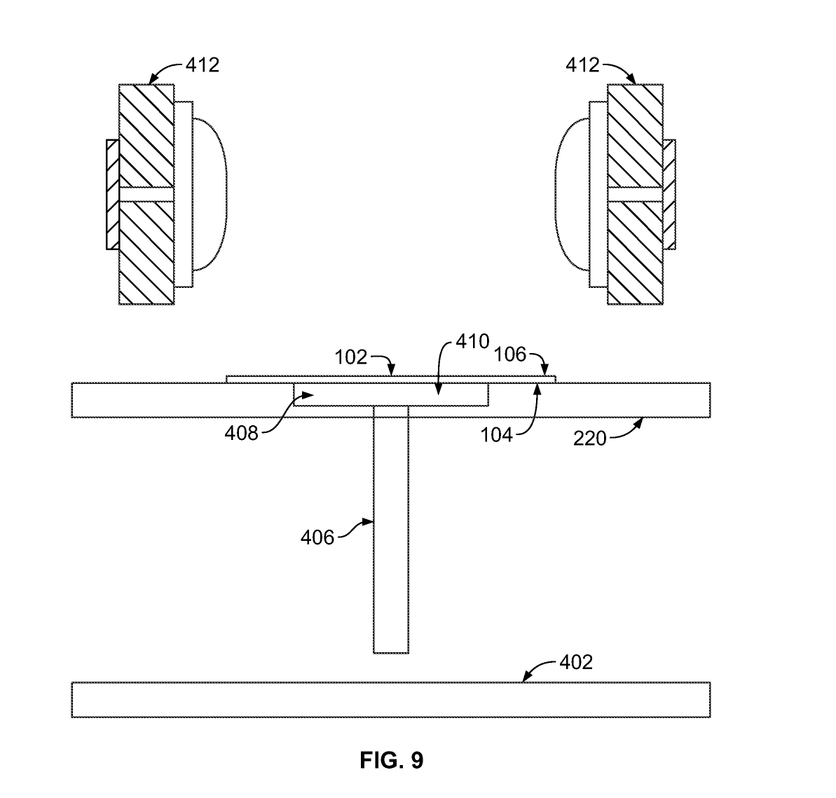

The method 800 begins at 802, with the body 102 entering the flipping chamber 202e. FIG. 9, with continued reference to the method of FIG. 8, illustrates a body 102 in a carrier 220 positioned under a grasping cell 405 in a flipping chamber 202e. Upon entering the chamber 202e, the orientation of the body 102 may be such that the facing side 104 faces the carrier 220, and the exposed side 106 is exposed (e.g., faces the grasping cell 405). The body 102 may rest on the surface of the carrier 220 and on the plug 408. As shown, the plug 408 and the post 406 are in the lowered position. As such, the plug 408 may reside within the recess 410. Furthermore, as shown in FIG. 9, because the recess 410 maintains the plug 408, the post 406 may not contact or touch the lifting plate 402.

The carrier 220 may be transported into the flipping chamber 202e by a conveyor subsystem. The conveyor subsystem may move the carrier 220 into the flipping chamber 220 until the body 102 is aligned under a grasping cell 405. The body 102 may be aligned such that the geometric center of the body 102 as seen from a plan form view substantially coincides with the center of the grasping cell 404. To align the body 102, the conveyor subsystem may continue to move the body 102 into the flipping chamber 202e until body 102 is in the appropriate position (e.g., aligned). After the body 102 is positioned under the grasping cell 405, the method may proceed to 804.

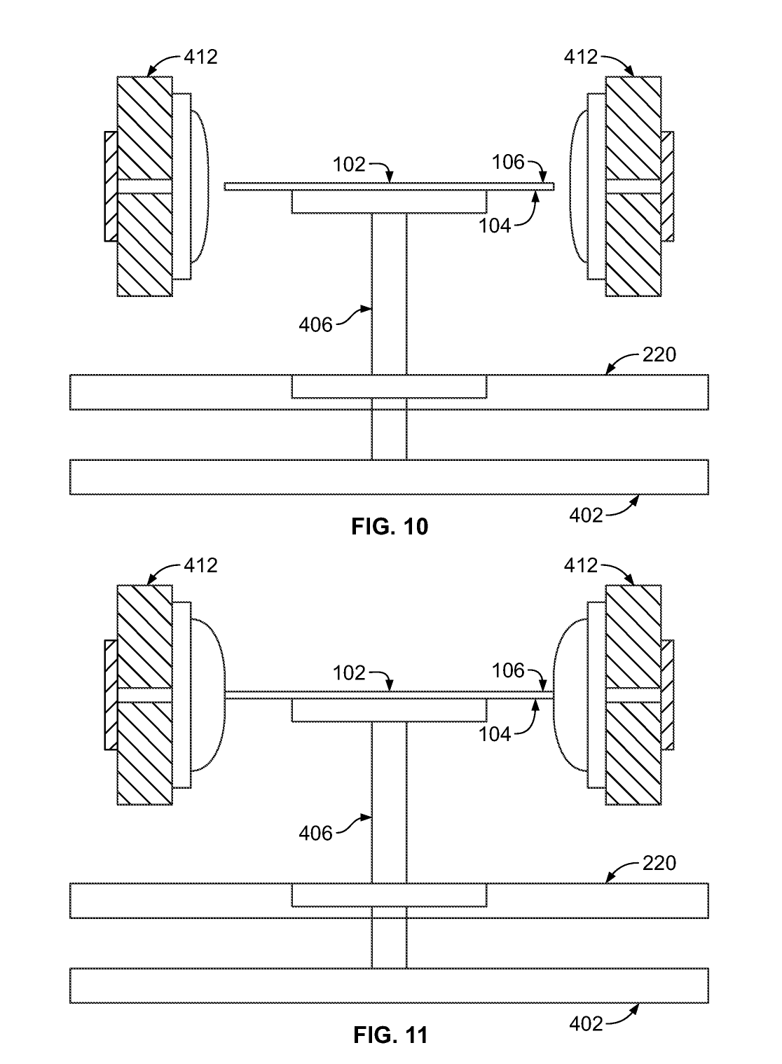

At 804, the lifting plate 402 may move toward the grasping cell 405 to cause the post 406 and plug 408 to transition to the raised position and, as such, to raise the body 102 into the grasping cell 405. FIG. 10 depicts the lifting plate 402 contacting the post 406 to raise the body 102. To raise the body 102 into the grasping cell 405, the lifting plate 402 contacts the post 406 and causes the post 406 to transition from the lowered position to the raised position. The lifting operation may begin with the lifting plate 402 contacting the post 406. After contacting the post 406, the lifting plate 402, plug 408 and the body 102 may continue to travel toward the grasping cell 405. The lifting plate 402, post 406, plug 408, and the body 102 may continue to travel until the body 102 reaches a select position. For example, the lifting plate may continue to move toward the grasping cell 405 until the horizontal axis of the body 102 (e.g., as seen from an elevation view) approaches the center of the grasping cell 405. As another example, the lifting plate move upward toward the grasping cell 405 until the body 102 passes a predetermined landmark. For example, the landmark may be the center of the membrane 414. Alternatively, the lifting plate 402 may continue to move until the lifting plate 402 contacts the carrier 220. After the lifting plate 402 delivers the body to the grasping cell 405, the method may continue to 806.

At 806, the grasping bodies 412 may engage the body 102. FIG. 11 illustrates the post 406 and plate 402 in the raised position with the grasping bodies 412 engaging the body 102. To engage the body 102, the delivery channel 504 may introduce fluid into the internal volume 413 to cause the membrane 414 to expand. For example, the pressure inside the internal volume 413 may be increased to 5 Torr whereas the ambient pressure inside the chamber 202e remains less than 5 Torr. Thus the pressure difference between the pressure within the internal volume 413 and the ambient pressure within the chamber 202e may cause the membrane 414 to expand. Optionally, hydraulic fluid may be introduced into the internal volume 413 to cause the membrane 414 to expand. The membrane 414 may expand or inflate to contact or partially envelope at least one edge of the body 102. When the membrane is in the expanded state, the gripping bodies 412 may support the weight of the body 102. When the grasping body 412 holds the body 102, the grasping body 412 supports the body 102 no longer rests on the plug 408. After the grasping bodies 412 engage the body 102, the method may continue to 808.

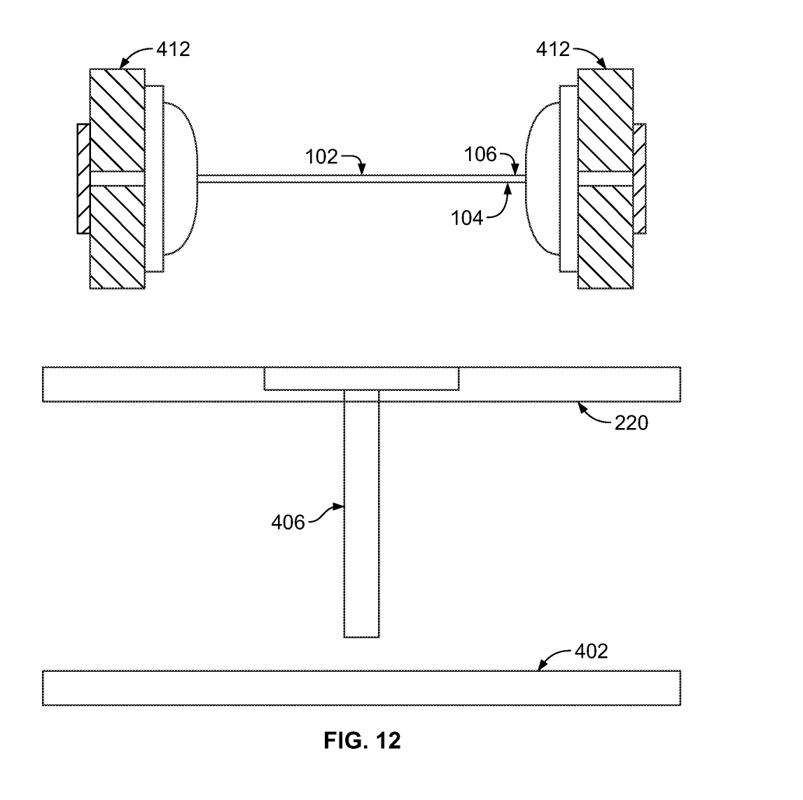

At 808, the post 406 and plug 408 may return to the lowered position while the grasping bodies 412 hold and retain the body 102 in the grasping cell 405. FIG. 12 is a diagram illustrating the lift plate 402 retreating from the grasping cell 405 with the grasping bodies 412 holding the body 102. The grasping bodies 412 remains engaged with the body 102 such that the grasping body 412 supports the body 102. The post 406, plug 408, and lifting plate 402 may then recede below the grasping cell 405 and return to the lowered position. As discussed above, in the lowered position, the plug 408 supports the post 406 within the carrier 220. The post 406 may then no longer engage or contact the lifting plate 402. After the post 406, plug 408, and lifting plate 402 have returned to the lowered position, the method may continue to 810.

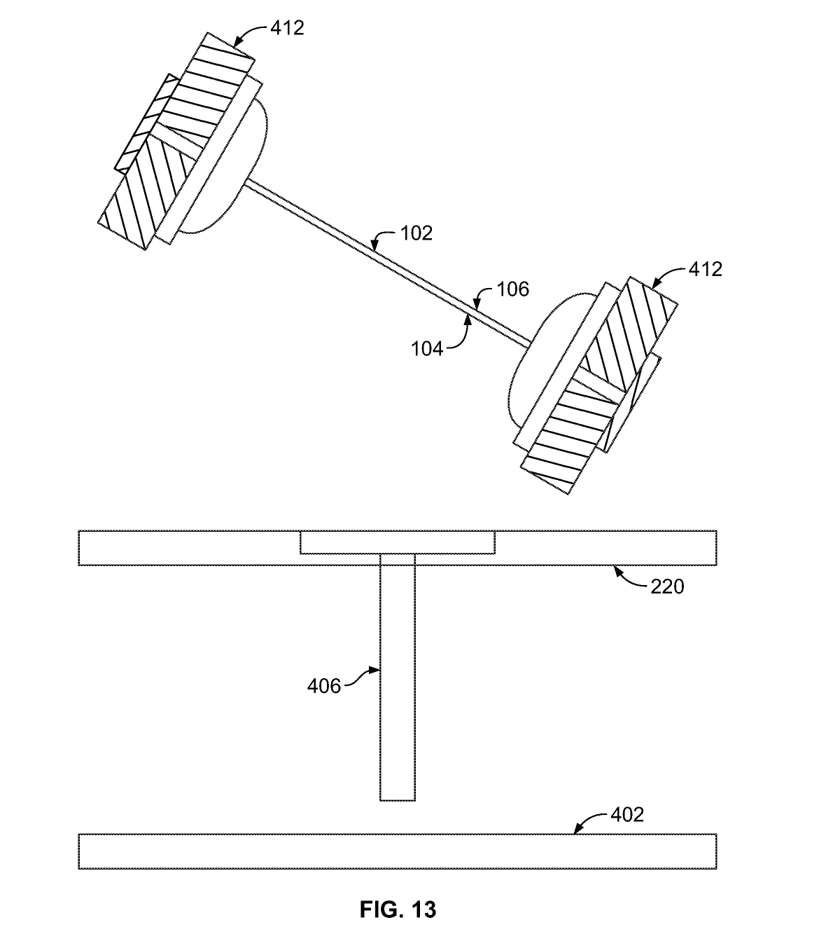

At 810 the grasping cell array 404 changes the orientation of the body 102. For example, the grasping cell array 404 may rotate or flip the body 102. FIG. 13 is a diagram illustrating the grasping bodies 412 engaging the body 102 while the body 102 is rotated. In order to rotate the body 102, the rotation shaft 420 may be caused to rotate. The rotation shaft 420 may include provisions (e.g., an electric drive system) to cause the rotation shaft 420 to rotate. As the rotation shaft rotates, the grasping cell array 404 also rotates. Thus, the grasping cells 405 within the grasping cell array 404 also rotate. Similarly, the grasping bodies 412 also rotate. Further, because the grasping bodies 412 remain engaged with the body 102, the body 102 is also caused to rotate. The rotation shaft 420 may rotate a desired number of revolutions to change the orientation of the body 102. For example, the body 102 may be rotated 180° to flip the body 102.

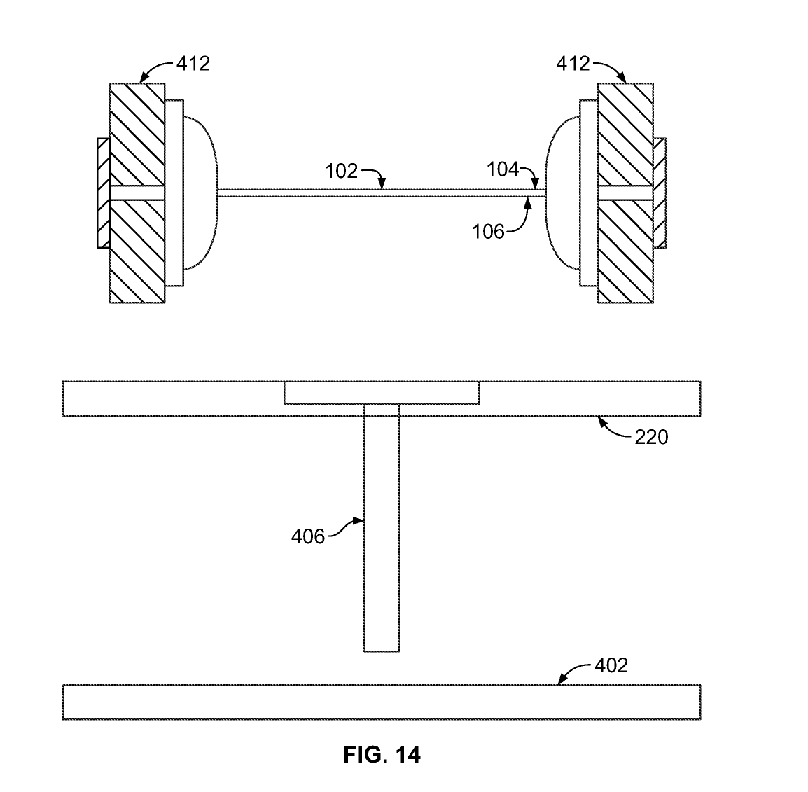

FIG. 14 is a diagram illustrating the body 102 after being rotated. As such, after being rotated, the exposed side 106 of the body 102 may no longer be exposed and the facing side 104 may no longer face the carrier. Thus, rotating the body 180° may invert the orientation of the body 102 such that the exposed side 106 now faces the carrier and the facing side 104 becomes exposed. After the body 102 has been flipped or rotated a desired number of revolutions, the method may continue to 812.

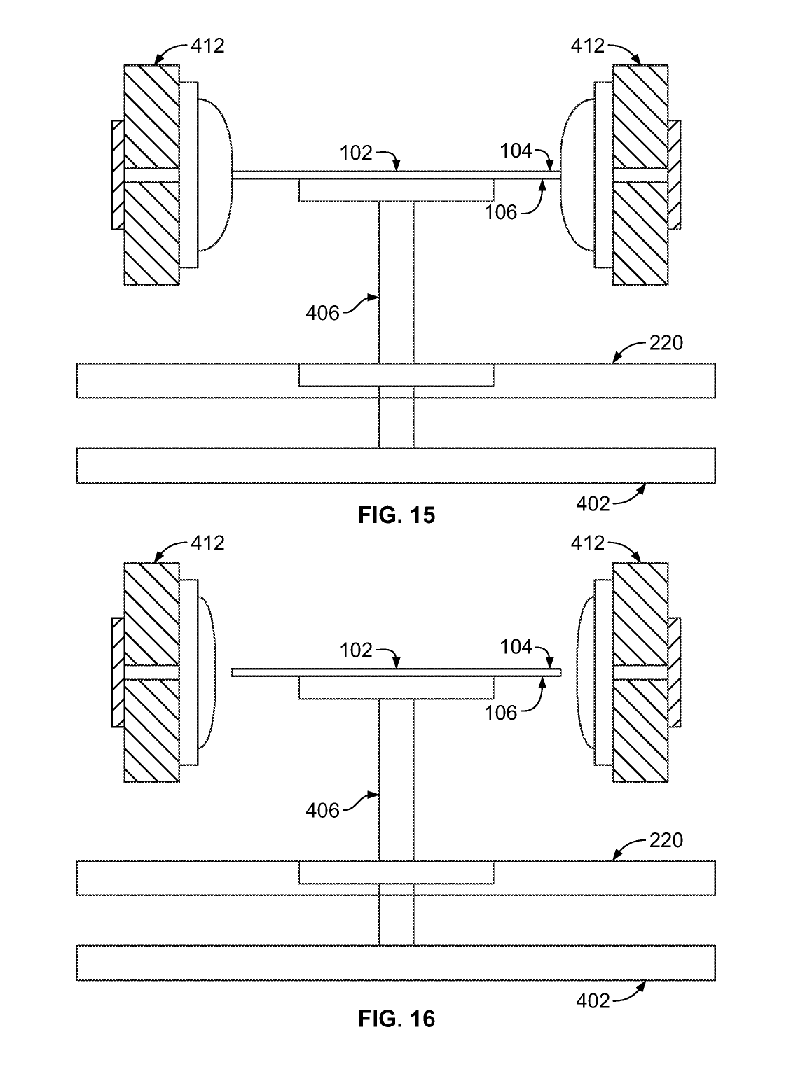

At 812, the lifting plate 402 approaches the grasping cell array 404 to cause the post 406 to become raised in order to retrieve the body 102. FIG. 15 is a diagram showing the lifting plate 402 contacting and raising the post 406 to retrieve the body 102 form the grasping cell 405. As described above in relation to 804, the lifting plate 402 may move toward the grasping cell 405 (e.g., upward). While moving, the lifting plate 402 may contact the post 406. As the lifting plate 402 continues to travel toward the grasping cell 405, the lifting plate 402 may also lift the post 406 and plug 408. The lifting plate 402, post 406, and plug 408 continue to travel until the plug 408 reaches body 102. The plug 408 may then contact the body 102. After the plug 408 reaches the body 102, the method may continue to 814.

At 814, the grasping bodies 412 release the body 102 onto the plug 408. FIG. 16 is a diagram illustrating the grasping bodies 412 releasing the body 102 onto the plug 408. To release the body 102, the grasping bodies 412 may retract away from an edge of the body 102. In an embodiment, the fluid level in the internal volume 413 may be decreased thus forcing the membrane 414 of the grasping bodies 412 to contract. For example, air pressure inside delivery channel 504 and the internal volume 413 may be reduced to be less than or equal to the ambient pressure inside the chamber 202e. Thus, the pressure equalization may cause the membrane 414 of the grasping body 412 to contract and no longer contact or engage an edge of the body 102. Thus, the grasping bodies 412 release to body 102. The body 102 may then rest on the surface of the plug 408. After the body 102 is transferred to the plug 408, the method continues to 816.

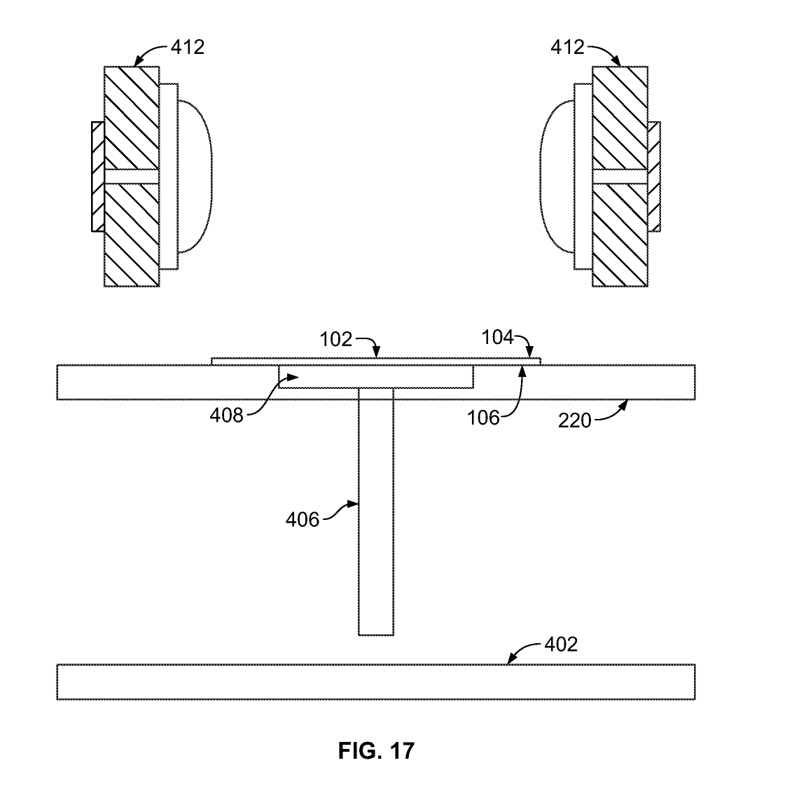

At 816, lifting plate 402 lowers the body 102 onto the carrier 220. FIG. 17 is a diagram illustrating the post 406, the plug 408, and the body 102 in the lowered position. Once lowered, the body 102 may rest on the carrier 220. The recess 410 may receive the plug 408, thus suspending the post 406. The lifting plate 402 may continue to travel away from the carrier 220 and the grasping cell 405 such that the lifting plate 402 no longer contacts the post 406. After the lifting plate 402 no longer contacts the post 406, the method may continue to 818.

At 818, the conveyor system may transport the carrier 220 out of the flipping chamber 202e. The process may then be repeated one or more times as required to complete processing of the body 102 in order to manufacture the module 100.

In another embodiment, a method of manufacturing semiconductor devices such as photovoltaic modules comprising of modifying a first side of a first semiconductor body inside of a processing system to at least partially manufacture one or more photovoltaic modules, then flipping the first semiconductor body over inside the processing system, and modifying an opposite, second side of the first semiconductor body inside of the processing system to continue fabrication of the one or more photovoltaic cells. Wherein the modifying of the at least one of the first side or second side of the first semiconductor body is performed in a at least one of a reduced pressure or an increased temperature environment of the processing system. Further the flipping the first semiconductor body is performed without removing the first semiconductor body from the processing system.

In another aspect, the modifying at least one of the first side or the second side of the first semiconductor body inside the processing system includes at least one of depositing a layer onto the first semiconductor body, etching the semiconductor body, or annealing the semiconductor body.

In another aspect, the first semiconductor body is conveyed through the processing system on a carrier, and further comprising lifting the first semiconductor body from the carrier prior to flipping the first semiconductor body without removing the first semiconductor body from the processing system.

In another aspect, the first side of the first semiconductor body is exposed and the second side of the first semiconductor body faces a carrier that supports the first semiconductor body during modification of the first side of the first semiconductor body, and

In another aspect, the first semiconductor body exposes the second side of the first semiconductor body and causes the first side of the first semiconductor body to face the carrier.

In another aspect, flipping the semiconductor body inverts the orientation of the body such that the first side faces the direction held by the second side prior to the flipping.

In another aspect, the first semiconductor body is flipped inside the processing system without entry of a manual operator or an external object into the processing system from outside of the processing system.

In another aspect, the first semiconductor body is flipped over inside a chamber of the processing system that is under the reduced pressure environment without breaking the reduced pressure environment of the chamber.

In another aspect, the method further comprises engaging the first semiconductor body with one or more grasping bodies to hold the first semiconductor body during flipping of the first semiconductor body.

In another aspect, the one or more grasping bodies engage one or more edges of the first semiconductor body that extend from the first side to the second side of the first semiconductor body.

In another aspect, the one or more grasping bodies engage the one or more edges of the first semiconductor body in two or more locations that are opposite each other.

In another aspect, the grasping bodies engage a first edge and second edge of the body, wherein the first edge is diametrically opposed to the second edge; the first and second edge adjoining the first and the second side of the body.

In another aspect, the one or more grasping bodies include one or more inflatable bodies. Additionally, engaging the first semiconductor body includes inflating the one or more inflatable bodies with a fluid to cause the one or more inflatable bodies to expand and engage the first semiconductor body.

In another aspect, the inflatable bodies surround the perimeter of the semiconducting body.

In another aspect, the inflatable bodies are removably coupled to the flipping assembly.

In another aspect, the processing system is configured to concurrently modify the first and second sides of plural semiconductor bodies that include the first semiconductor body, and the one or more inflatable bodies includes plural inflatable bodies arranged in plural sets with each of the sets configured to engage a different respective semiconductor body of the semiconductor bodies, and wherein the sets of the inflatable bodies are fluidly coupled with each other such that the sets of inflatable bodies are concurrently inflated by the fluid.

In another aspect, the fluid is a gas.

In another aspect, the fluid is a liquid.

In another aspect, a common fluid conduit provides fluid to the inflatable bodies concurrently.

In another aspect, a rotatable shaft is configured to be coupled with a flipping assembly and to rotate in order to rotate the flipping assembly. Additionally, the flipping assembly is configured to be rotated by the shaft while the one or more inflatable bodies hold the semiconductor body so that the semiconductor body is flipped over.

In another embodiment, a processing system (e.g., a system for forming one or more semiconductor layers on a device) includes one or more upstream chambers configured to modify a first side of a first semiconductor module inside the processing system to at least partially manufacture one or more photovoltaic cells. The system also includes a flipping assembly configured to be disposed inside a flipping chamber that is downstream from the one or more upstream chambers and configured to receive the first semiconductor body from the one or more upstream chambers, the flipping assembly configured to flip the first semiconductor body over inside the processing system. Additionally, the system includes one or more downstream chambers configured to receive the first semiconductor body after being flipped by the flipping assembly and to modify a second side of a first semiconductor body inside the processing system to at least partially manufacture one or more photovoltaic cells. Additionally, the one or more upstream chambers or the one or more downstream chambers are configured to modify the respective first or second side of the semiconductor body in at least one of a reduced pressure or an increased temperature environment, and the flipping assembly is configured to flip the first semiconductor body over without removing the first semiconductor body from the flipping chamber.

In another aspect, modifying at least one of the first side or the second side of the first semiconductor body inside the processing system includes at least one of depositing a layer onto the first semiconductor body, etching the semiconductor body, or annealing the semiconductor body.

In another aspect, the first semiconductor body is conveyed through the processing system on a carrier, and further comprising lifting the first semiconductor body from the carrier prior to flipping the first semiconductor body without removing the first semiconductor body from the processing system.

In another aspect, the first side of the first semiconductor body is exposed and the second side of the first semiconductor body faces a carrier that supports the first semiconductor body during modification of the first side of the first semiconductor body, and flipping the first semiconductor body exposes the second side of the first semiconductor body and causes the first side of the first semiconductor body to face the carrier.

In another aspect, flipping inverts the orientation of the body such that the first side faces the direction held by the second side prior to the flipping.

In another aspect, the flipping assembly is configured to flip the first semiconductor body over inside the processing system without entry of a manual operator or an external object into the processing system from outside of the processing system.

In another aspect, the first semiconductor body is flipped over inside a chamber of the processing system that is under the reduced pressure environment without breaking the reduced pressure environment of the chamber.

In another aspect, the flipping assembly is configured to engage the first semiconductor body with one or more grasping bodies to hold the first semiconductor body during flipping of the first semiconductor body.

In another aspect one or more grasping bodies engage one or more edges of the first semiconductor body that extend from the first side to the second side of the first semiconductor body.

In another aspect, one or more grasping bodies engage the one or more edges of the first semiconductor body in two or more locations that are opposite each other.

In another aspect, the grasping bodies engage a first edge and second edge of the body, such that the first edge is diametrically opposed to the second edge and the first and second edge adjoining the first and the second side of the body.

In another aspect, the one or more grasping bodies include one or more inflatable bodies, and wherein engaging the first semiconductor body includes inflating the one or more inflatable bodies with a fluid to cause the one or more inflatable bodies to expand and engage the first semiconductor body.

In another aspect, the inflatable bodies surround the perimeter of the semiconducting body.

In another aspect, the inflatable bodies are removably coupled to the flipping assembly.

In another aspect, the processing system is configured to concurrently modify the first and second sides of plural semiconductor bodies that include the first semiconductor body. Additionally, the one or more inflatable bodies includes plural inflatable bodies arranged in plural sets with each of the sets configured to engage a different respective semiconductor body of the semiconductor bodies. Further, the sets of the inflatable bodies are fluidly coupled with each other such that the sets of inflatable bodies are concurrently inflated by the fluid.

In another aspect, the fluid is an incompressible fluid.

In another embodiment, flipping system (e.g., a chamber in a multi-chamber processing system) includes a lifting plate configured to move relative to a carrier that holds a semiconductor body above an opening through the carrier. Additionally, the flipping system includes a post connected with the lifting plate and configured to move through the opening in the carrier. The post is configured to separate the semiconductor body from the carrier when the lifting plate moves toward the carrier. Further, the flipping system includes a flipping assembly configured to receive the semiconductor body when the post separates the semiconductor body from the carrier. The flipping assembly including one or more inflatable bodies configured to be inflated with a fluid in order to expand and engage the semiconductor body. Additionally, the flipping system includes a rotatable shaft configured to be coupled with the flipping assembly and to rotate in order to rotate the flipping assembly. The flipping assembly is configured to be rotated by the shaft while the one or more inflatable bodies hold the semiconductor body so that the semiconductor body is flipped over.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the inventive subject matter without departing from its scope. While the dimensions, types of materials and coatings described herein are intended to define the parameters of the inventive subject matter, they are by no means limiting and are exemplary embodiments. Many other embodiments will be apparent to those of skill in the art upon reviewing the above description. The scope of the inventive subject matter should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

This written description uses examples to disclose the various embodiments of the inventive subject matter, including the best mode, and also to enable any person of ordinary skill in the art to practice the various embodiments of the inventive subject matter, including making and using any devices or systems and performing any incorporated methods. The patentable scope of the various embodiments of the inventive subject matter is defined by the claims, and may include other examples that occur to those of ordinary skill in the art. Such other examples are intended to be within the scope of the claims if the examples have structural elements that do not differ from the literal language of the claims, or if the examples include equivalent structural elements with insubstantial differences from the literal languages of the claims.

What is claimed is:

1. A method comprising:
modifying a first side of a first semiconductor body inside of a processing system to at least partially manufacture one or more photovoltaic modules;
flipping the first semiconductor body over inside the processing system; and
modifying an opposite, second side of the first semiconductor body inside of the processing system to continue fabrication of the one or more photovoltaic cells,
wherein modifying at least one of the first side or second side of the first semiconductor body is performed in a at least one of a reduced pressure or an increased temperature environment of the processing system and flipping the first semiconductor body is performed without removing the first semiconductor body from the processing system.

2. The method of claim 1, wherein the first semiconductor body is conveyed through the processing system on a carrier, and further comprising lifting the first semiconductor body from the carrier prior to flipping the first semiconductor body without removing the first semiconductor body from the processing system.

3. The method of claim 1, wherein the first side of the first semiconductor body is exposed and the second side of the first semiconductor body faces a carrier that supports the first semiconductor body during modification of the first side of the first semiconductor body, and
wherein flipping the first semiconductor body exposes the second side of the first semiconductor body and causes the first side of the first semiconductor body to face the carrier.

4. The method of claim 1, wherein the first semiconductor body is flipped inside the processing system without entry of a manual operator or an external object into the processing system from outside of the processing system.

5. The method of claim 1, wherein the first semiconductor body is flipped over inside a chamber of the processing system that is under the reduced pressure environment without breaking the reduced pressure environment of the chamber.

6. The method of claim 1, further comprising engaging the first semiconductor body with one or more grasping bodies to hold the first semiconductor body during flipping of the first semiconductor body.

7. The method of claim 6, wherein the one or more grasping bodies include one or more inflatable bodies, and wherein engaging the first semiconductor body includes inflating the one or more inflatable bodies with a fluid to cause the one or more inflatable bodies to expand and engage the first semiconductor body.

8. The method of claim 7, wherein the processing system is configured to concurrently modify the first and second sides of plural semiconductor bodies that include the first semiconductor body, and the one or more inflatable bodies includes plural inflatable bodies arranged in plural sets with each of the sets configured to engage a different respective semiconductor body of the semiconductor bodies, and wherein the sets of the inflatable bodies are fluidly coupled with each other such that the sets of inflatable bodies are concurrently inflated by the fluid.

9. The method of claim 7, wherein a rotatable shaft is configured to be coupled with a flipping assembly and to rotate in order to rotate the flipping assembly, wherein the flipping assembly is configured to be rotated by the shaft while the one or more inflatable bodies hold the semiconductor body so that the semiconductor body is flipped over.

10. A processing system comprising:
one or more upstream chambers configured to modify a first side of a first semiconductor module inside the processing system to at least partially manufacture one or more photovoltaic cells;
a flipping assembly configured to be disposed inside a flipping chamber that is downstream from the one or more upstream chambers and configured to receive the first semiconductor body from the one or more upstream chambers, the flipping assembly configured to flip the first semiconductor body over inside the processing system; and
one or more downstream chambers configured to receive the first semiconductor body after being flipped by the flipping assembly and to modify a second side of a first semiconductor body inside the processing system to at least partially manufacture one or more photovoltaic cells;
wherein at least one of the one or more upstream chambers or the one or more downstream chambers are configured to modify the respective first or second side of the semiconductor body in at least one of a reduced pressure or an increased temperature environment, and
wherein the flipping assembly is configured to flip the first semiconductor body over without removing the first semiconductor body from the flipping chamber.

11. The processing system of claim 10, wherein the first semiconductor body is conveyed through the processing system on a carrier, and further comprising lifting the first semiconductor body from the carrier prior to flipping the first semiconductor body without removing the first semiconductor body from the processing system.

12. The processing system of claim 10, wherein the first side of the first semiconductor body is exposed and the second side of the first semiconductor body faces a carrier that supports the first semiconductor body during modification of the first side of the first semiconductor body, and
wherein flipping the first semiconductor body exposes the second side of the first semiconductor body and causes the first side of the first semiconductor body to face the carrier.

13. The processing system of claim 10, wherein the flipping assembly is configured to flip the first semiconductor body over inside the processing system without entry of a manual operator or an external object into the processing system from outside of the processing system.

14. The processing system of claim 10, wherein the first semiconductor body is flipped over inside a chamber of the processing system that is under the reduced pressure environment without breaking the reduced pressure environment of the chamber.

15. The processing system of claim 10, wherein the flipping assembly is configured to engage the first semiconductor body with one or more grasping bodies to hold the first semiconductor body during flipping of the first semiconductor body.

16. The processing system of claim 15, wherein the one or more grasping bodies engage one or more edges of the first semiconductor body that extend from the first side to the second side of the first semiconductor body.

17. The processing system of claim 15, wherein the one or more grasping bodies include one or more inflatable bodies, and wherein engaging the first semiconductor body includes inflating the one or more inflatable bodies with a fluid to cause the one or more inflatable bodies to expand and engage the first semiconductor body.

18. The method of claim 17, wherein the inflatable bodies are removably coupled to the flipping assembly.

19. The processing system of claim 17, wherein the processing system is configured to concurrently modify the first and second sides of plural semiconductor bodies that include the first semiconductor body, and the one or more inflatable bodies includes plural inflatable bodies arranged in plural sets with each of the sets configured to engage a different respective semiconductor body of the semiconductor bodies, and wherein the sets of the inflatable bodies are fluidly coupled with each other such that the sets of inflatable bodies are concurrently inflated by the fluid.

20. A flipping system comprising:
a lifting plate configured to move relative to a carrier that holds a semiconductor body above an opening through the carrier;
a post connected with the lifting plate and configured to move through the opening in the carrier, the post configured to separate the semiconductor body from the carrier when the lifting plate moves toward the carrier;
a flipping assembly configured to receive the semiconductor body when the post separates the semiconductor body from the carrier, the flipping assembly including one or more inflatable bodies configured to be inflated with a fluid in order to expand and engage the semiconductor body; and
a rotatable shaft configured to be coupled with the flipping assembly and to rotate in order to rotate the flipping assembly, wherein the flipping assembly is configured to be rotated by the shaft while the one or more inflatable bodies hold the semiconductor body so that the semiconductor body is flipped over.
